(19) United States
(12) Patent Application Publication
(10) Pub. No.: US 2015/0015291 A1
(43) Pub. Date: Jan. 15, 2015

(54) CANTILEVER PROBE CARD FOR HIGH-FREQUENCY SIGNAL TRANSMISSION

(71) Applicant: MPI CORPORATION, ZHUBEI (TW)

(72) Inventors: WEI-CHENG KU, ZHUBEI (TW); Jun-Liang Lai, Zhubei (TW); Chun-Chung HUANG, Taipei (TW); Jing-Zhi Hung, Zhubei (TW); Yung Nan Wu, Tainan (TW); CHIH-HAO HO, Xinpu Township (TW)

(73) Assignee: MPI CORPORATION, ZHUBEI (TW)

(21) Appl. No.: 14/332,200

(22) Filed: Jul. 15, 2014

(30) Foreign Application Priority Data
Jul. 15, 2013 (TW) 102125230
Jul. 11, 2014 (TW) 103123948

(51) Int. Cl. G01R 1/067; G01R 1/073

(52) U.S. Cl. CPC G01R 1/06772; G01R 1/07307; G01R 1/06727; G01R 1/06738
USPC 324/755.07

(57) ABSTRACT

A cantilever probe card, which is provided between a device under test (DUT) and a tester, includes a carrier board, a probe base, two probes, and a transmission device. The carrier board is provided with through holes. The probe base is provided on the carrier board, and the probes are mounted to the probe base. Each probe has a tip to contact a test pad of the DUT. The transmission device is flexible, and has signal circuits. The transmission device passes through the through hole on the carrier board, and the signal circuits connect the probes to the tester respectively.

### BACKGROUND OF THE INVENTION

1. Technical Field

The present invention relates generally to a probe card, and more particularly to a cantilever probe card which is capable of transmitting high-frequency signals.

2. Description of Related Art

Cantilever robe cards are widely applied as transmission interfaces between a tester and a device under test (DUT) to test if every electronic component of the DUT is electrically connected correctly.

A conventional cantilever probe card is provided with a rigid multilayer PCB and a plurality of probes electrically connected to the PCB. The probes contact specified test pads of the DUT with their tips, and the PCB is electrically connected to the tester. Typically, the PCB is provided with several vias for electrical connection of conductor patterns on different layers. However, via stub effect will happen in the vias while high-frequency signals are being transmitted through the PCB. The via stub effect makes the inductance increase, and a resistance of the inductance increases while the frequency of the test signal is getting higher. A high resistance is bad for high-frequency signal transmission, and, sometime, it makes error in test.

Besides, the conventional probe card can't afford the high-frequency signals of a modern DUT. An improved probe card makes the DUT generate a test signal, and transmit it to the probe card, and then the probe card transmits the test signal back to the DUT for a loopback test. This kind of probe card usually provides a loopback device on the PCB at a side facing the tester that makes the test signal have to be transmitted for a long distance. In the long distance transmission of the test signal, it has a high risk that the test signal is affected by other elements unexpectedly, and it also generates a micro inductance in transmission. Therefore, a resistance of the circuit is getting higher while the frequency of the test signal is getting higher. It is bad for transmission of high-frequency signals as well, and, sometime, it makes error in test.

### BRIEF SUMMARY OF THE INVENTION

In view of the above, the primary objective of the present invention is to provide a cantilever probe card which is capable of transmitting high-frequency signals effectively.

The present invention provides a cantilever probe card, which is provided between a device under test (DUT) and a tester, including a carrier board having a first side and a second side, wherein the first side faces the tester, and the second side faces the DUT; a probe base provided on the second side of the carrier board, wherein the probe base is insulating; two probes each having a tip and a cantilever, wherein the probes are conductive; the cantilever is connected to the tip; and the tip contacts a test pad of the DUT; and a transmission device provided on the carrier board and electrically connected to the cantilevers of the probes respectively, wherein the transmission device is flexible, and has signal circuits; each of the signal circuits transmits test signals between one of the probes and the tester.

The present invention further provides a cantilever probe card, which is provided between a device under test (DUT) and a tester, including a carrier board; a probe base provided on the carrier board, wherein the probe base is insulating; two probes each having a tip and a cantilever, wherein the probes are conductive; the cantilever is connected to the tip, and the tip contacts a test pad of the DUT; a transmission device having signal circuits, wherein each of the signal circuits transmits test signals between one of the probes and the tester; and a loopback device electrically connected to the signal circuits. While the DUT transmits a high-frequency test signal to one of the probes, the high-frequency test signal is transmitted through the signal circuit of the transmission device and the loopback device in sequence, and then is transmitted back to the DUT through another of the probes.

Whereby, the cantilever probe card of the present invention is able to transmit high-frequency test signals efficiently.

### BRIEF DESCRIPTION OF THE SEVERAL VIEWS OF THE DRAWINGS

The present invention will be best understood by referring to the following detailed description of some illustrative embodiments in conjunction with the accompanying drawings, in which

FIG. 1 is a sketch diagram of a first preferred embodiment of the present invention;

FIG. 2 is a sketch diagram of a second preferred embodiment of the present invention;

FIG. 3 is a sketch diagram of a third preferred embodiment of the present invention;

FIG. 4 is a sketch diagram of a fourth preferred embodiment of the present invention;

FIG. 5 is a sketch diagram of a fifth preferred embodiment of the present invention;

FIG. 6 is a wave attenuation diagram of the fifth preferred embodiment of the present invention;

FIG. 7 is a sketch diagram of a sixth preferred embodiment of the present invention;

FIG. 8 is a sketch diagram of a seventh preferred embodiment of the present invention;

FIG. 9 is a sketch diagram of an eighth preferred embodiment of the present invention;

FIG. 10 is a sketch diagram of a ninth preferred embodiment of the present invention; and

FIG. 11 is a sketch diagram of a tenth preferred embodiment of the present invention.

### DETAILED DESCRIPTION OF THE INVENTION

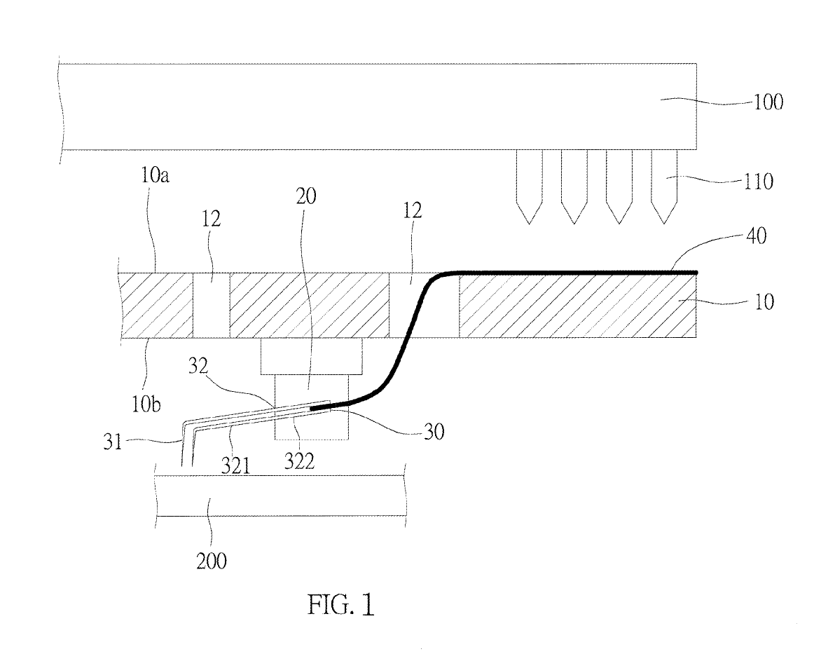

As shown in FIG. 1, a cantilever probe card of the first preferred embodiment of the present invention is provided between a tester 100 and a device under test (DUT, such as a processor) 200 to transmit test signals from the tester 100 to the DUT 200. The cantilever probe card includes a carrier board 10, a probe base 20, two probes 30, and a transmission device 40.

The carrier board 10 is a rigid printed circuit board (PCB) with a conductor pattern (not shown). The carrier board 10 has a first side 10a and a second side 10b while the first side 10a faces the tester 100, and the second side 10b faces the DUT 200. The carrier board 10 is provided with several through holes 12 which are open at both the first and the second sides 10a, 10b.

The probe base 20 is provided on the second side 10b of the carrier board 10 besides the through holes 12. The probe base 20 is made of epoxy to provide the probe base 20 with some properties, such as insulation and vibration absorption. In another embodiment, the probe base 20 is made of an insulating material.

Each probe 30 is a single conductive needle, having a tip 31 and a cantilever 32. The tip 31 is the designated portion to contact a test pad (not shown) on the DUT 200. The cantilever 32 has a first section 321 and a second section 322, wherein an end of the first section 321 is connected to the tip 31, and the other end thereof is connected to the second section 322. The tip 31 and the first section 321 are left out of the probe base 20 while the second section 322 is embedded in the probe base 20.

The transmission device 40 is a single-layer flexible printed circuit board (FPCB) in the present embodiment, on which signal circuits (not shown) are provided for signal transmission. The transmission device 40 is inserted into one of the through holes 12 of the carrier board 10 with opposite ends thereof left out of the through hole 12. The signal circuits extend to the end, which faces the tester 100, of the transmission device 40 to contact test terminals 110 of the tester 100 respectively. The signal circuits also extend to the opposite end, which faces the DUT 200, to be electrically connected to the second sections 322 of the probes 30 respectively.

As a result, each test terminal 110 of the tester 100 is electrically connected each probes through the signal circuits of the transmission device 40. Test signals generated by the tester 100 will be transmitted to the DUT 200 through the test terminal 110, the signal circuit of the transmission device 40, the probe 30, and the test pad of the DUT 200 in sequence. After that, the test signals are transmitted back to the tester 100 via another test pad (through another probe 30 and signal circuit) to be tested in the tester 100. It is obvious that the test signals are transmitted through the transmission device 40 and the probe 30 only. The element and circuit of the carrier board 10 will not affect the signal transmission. The only function of the transmission device 40 is signal transmission, no via has to be provided on the transmission device 40, so that no via stub effect will happen to the transmission device 40. As a result, the high-frequency signals may be transmitted through the transmission device 40 without interference to avoid error in test.

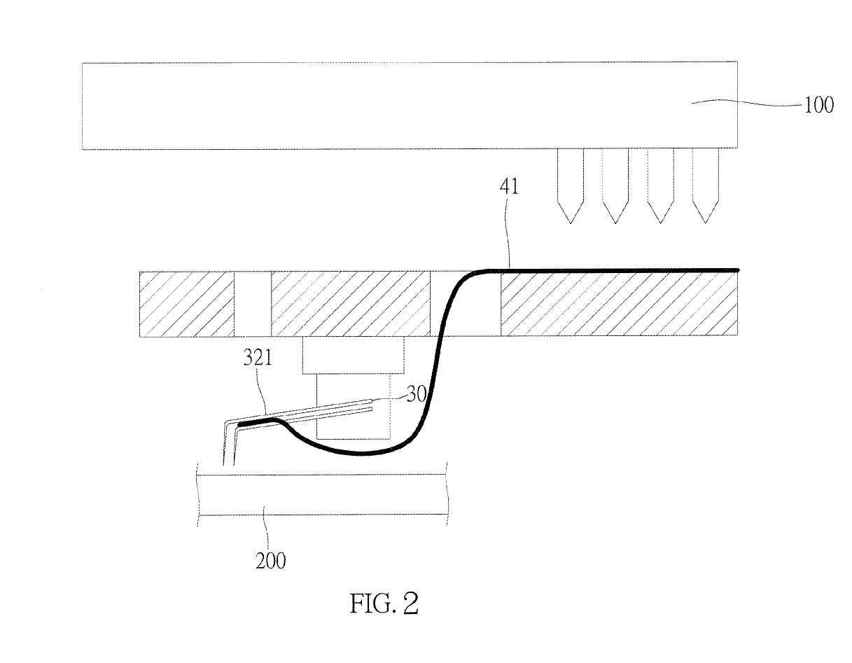

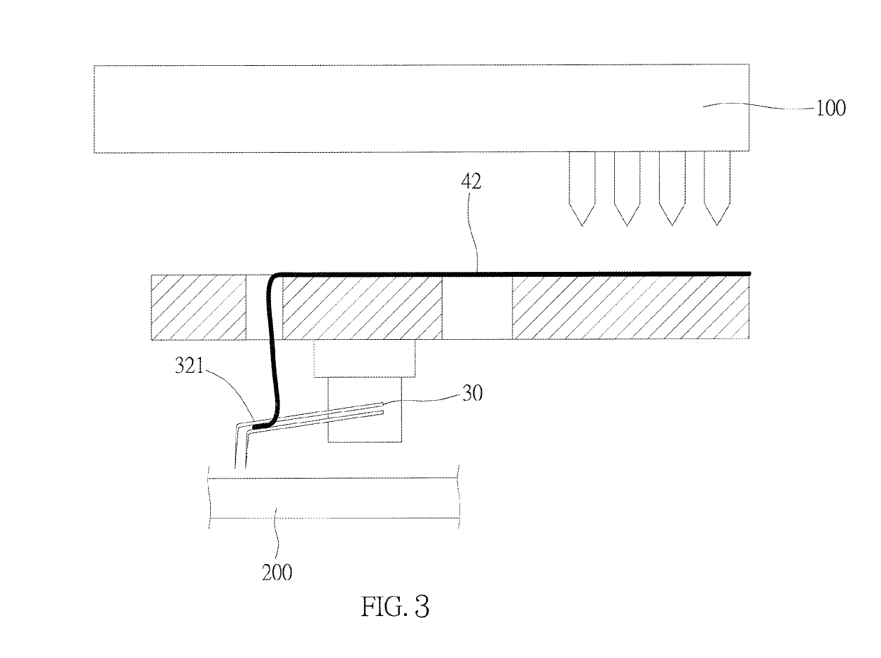

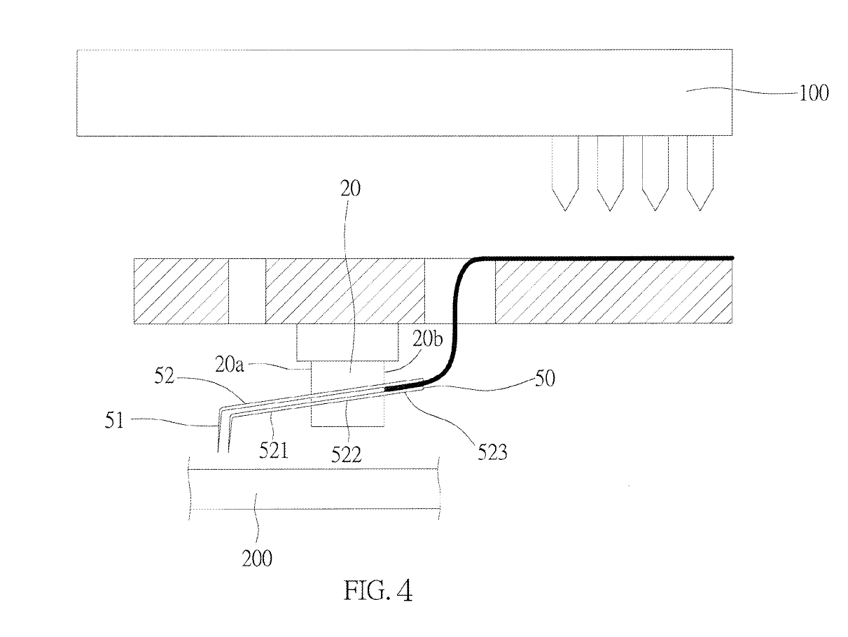

FIG. 2 and FIG. 3 show the second and the third preferred embodiments of the present invention, in which a transmission device 41 or 42 is connected to the first section 321 of the probe 30. They perform the same function as above. FIG. 4 shows a cantilever probe card of the fourth preferred embodiment of the present invention, in which the probe base 20 has a first side 20a and a second side 20b, and probes 50 are longer. Each probe 50 of the fourth preferred embodiment has a tip 51 and a cantilever 52, and the cantilever 52 has a first section 521, a second section 522, and a third section 523 in sequence. The second section 522 is embedded in the probe base 20 while the first and the second sections 521, 523 extend out of the probe base 20 via the first side 20a and the second side 20b respectively. A transmission device 43 is connected to the third section 523, and the first section 521 is connected to the tip 51. This structure provides the probes a strong support.

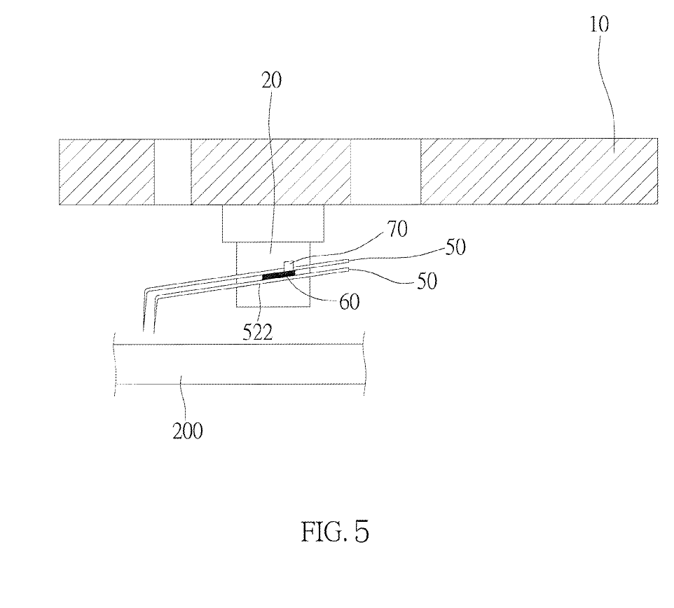

FIG. 5 shows a cantilever probe card of the fifth preferred embodiment of the present invention for a loopback test, which includes a carrier board 10, a probe base 20, two probes 50, a transmission device 60, and a loopback device 70. The structure and connection of the probe base 20 and the probes 50 are the same as above, so they are not described again. The transmission device 60 is a single-layer FPCB, and has signal circuits connected to the probes 50 respectively. The different part is that the transmission device 60 is embedded in the probe base 20, and the signal circuits are connected to the second sections 522. In the present embodiment, the loopback device 70 is a capacitor to transmit high-frequency signals only (the low-frequency signal couldn't be transmitted therethrough). In another embodiment, the loopback device 70 could be any device which can transmit high-frequency signals only. The loopback device 70 is welded onto the transmission device 60 to be electrically connected to one of the signal circuit thereof. The loopback device 70 is embedded in the probe base 20 as well to be firmly secured.

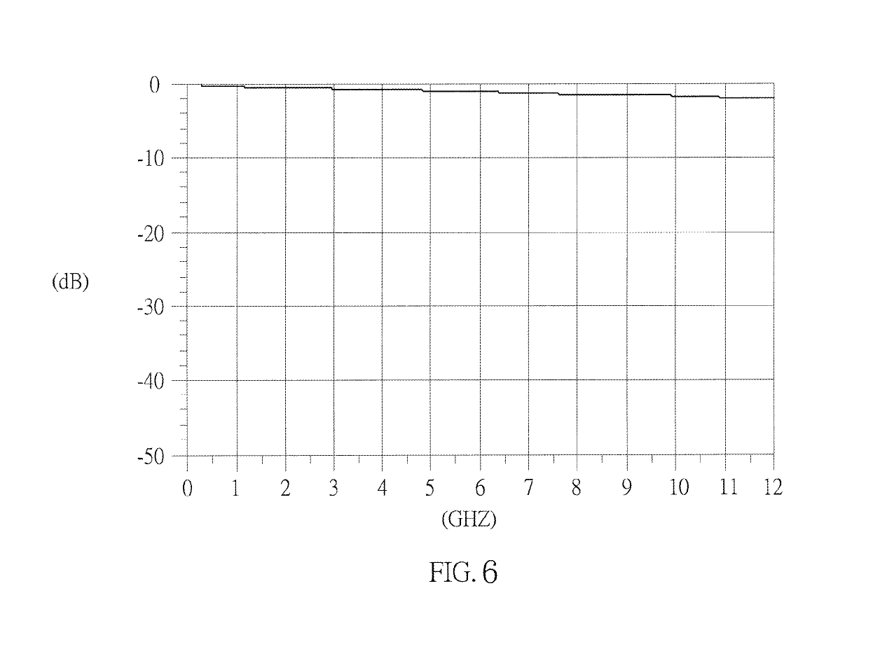

As a result, while the DUT 200 generates a high-frequency test signal, such as 12 Gbps, and transmits it to one of the probes 50. The test signal is transmitted through the signal circuit of the transmission device 60 and the loopback device 70 in sequence, and then goes back to the DUT 200 through another probe 30 for a loopback test. Such design can avoid interference and via stub effect, and, furthermore, it shortens a distance for signal transmission to reduce the micro inductance and resistance. FIG. 6 shows the cantilever probe card of the present invention may reduce the loss in transmission of high-frequency signals. As a result, the cantilever probe card of the present invention may perform the loopback test for the high-frequency signal, and no error in test will happen.

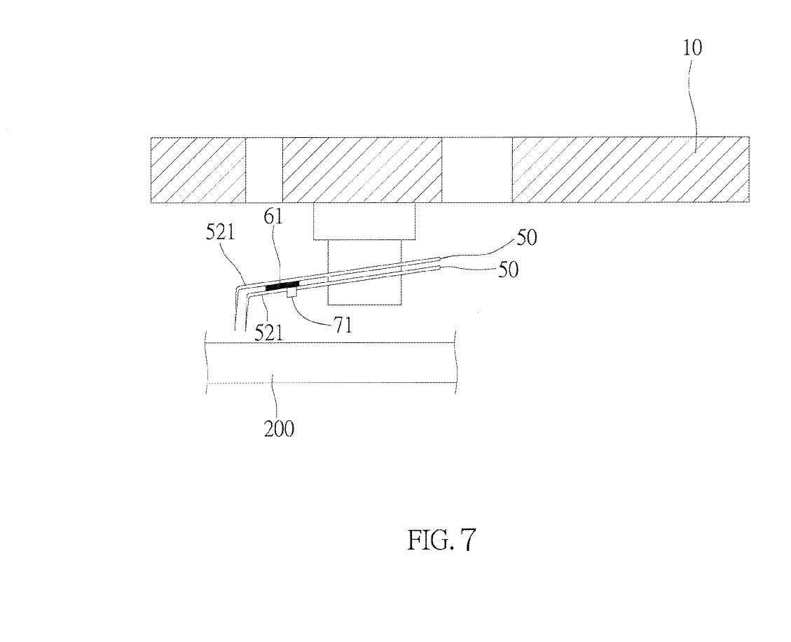

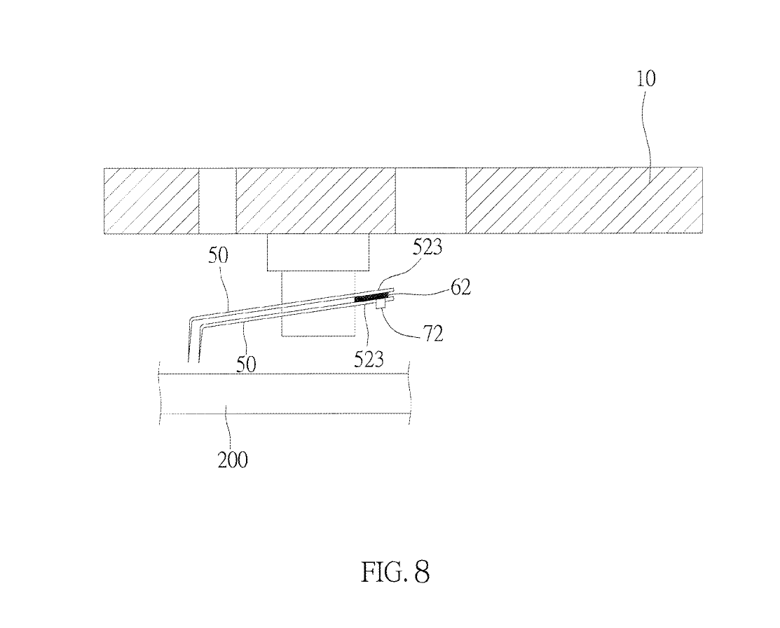

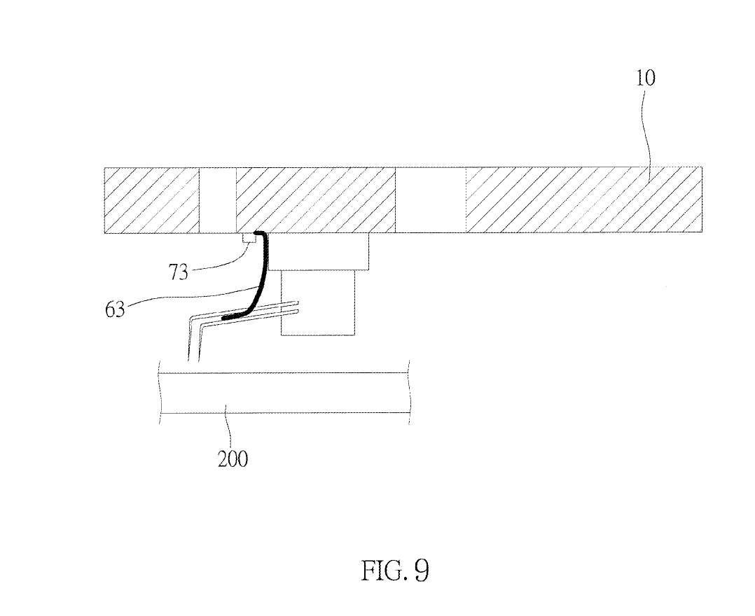

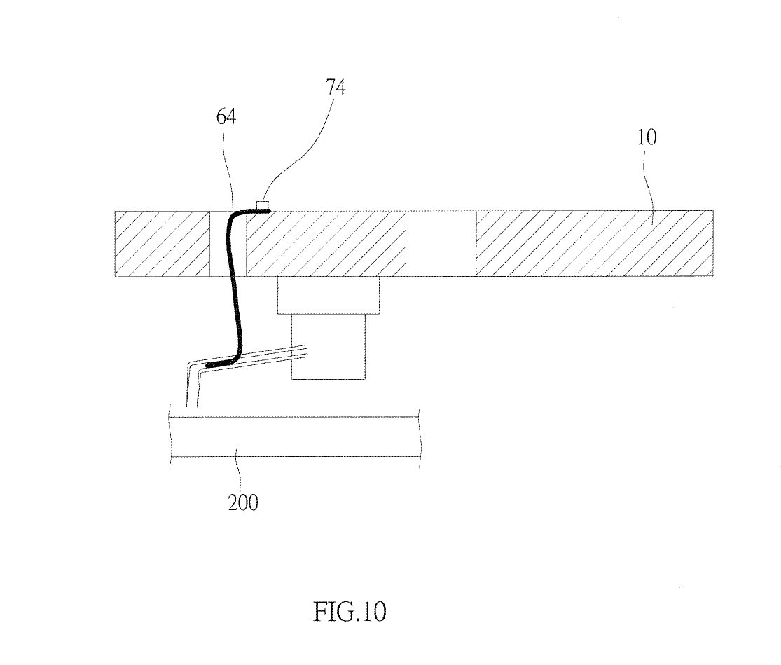

FIG. 7 and FIG. 8 show cantilever probe cards of the sixth and the seventh preferred embodiments of the present invention, in which transmission devices 61, 62 and loopback devices 71, 72 are connected to the first sections 521 or the third sections 523 of the probes 50 respectively. FIG. 9 and FIG. 10 show cantilever probe cards of the eighth and the ninth preferred embodiments of the present invention, in which transmission devices 63, 64 and loopback devices 73, 74 are respectively rested on the carrier board 10. They achieve the function the same as that of the fifth preferred embodiment.

Except the FPCB, the transmission device also could use a plurality of coaxial cables instead. The coaxial cables pass through the through holes of the carrier board respectively. Cores of the coaxial cables are the signal circuits of the transmission device.

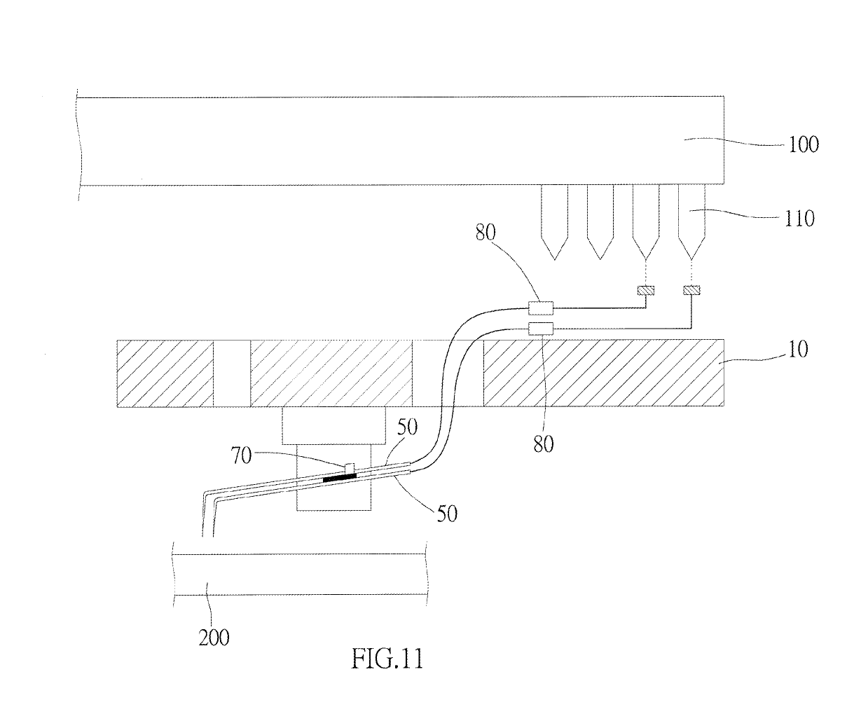

As shown in FIG. 11, a cantilever probe card of the tenth preferred embodiment of the present invention is similar to the cantilever probe card of the fifth preferred embodiment, and it further includes two inductive devices 80 provided on the carrier board 10. The inductive devices 80 are electrically connected to the probes 50 and the test terminals of the tester 100 respectively. In the present invention, the inductive devices 80 are chokes. In another embodiment, the inductive devices 80 could be coils, windings, beads, and other equivalent devices. The reason we choose the chokes is that choke is small in size, so that it could be mounted on any place of the carrier board 10, and the size of the carrier board 10 will not increase distinctly that makes the cantilever probe card thinner.

The inductive devices 80 have short circuits or low resistances, and loopback device 70 has an open circuit or a high resistance while a low-frequency test signal or a DC test signal from the test terminal 110 is transmitted to the DUT 200 through one of the inductive devices 80 and the probe 50, and then the test signal is transmitted to another probe 50, another inductive device 80 in sequence, and back to the tester 100. The inductive devices 80 may be incorporated in the cantilever probe cards of the sixth to the ninth embodiments for the same function.

In conclusion, with the designs of above the cantilever probe card of the present invention may transmit the high-frequency test signals between the tester 100 and the DUT 200, and transmit the test signals for loopback test without interference from other electric elements and without via stub effect problem. The present invention may reduce the micro inductance because of long distance transmission, and it may reduce the loss of test signal and the chance of error in test.

It must be pointed out that the embodiments described above are only some preferred embodiments of the present invention. All equivalent structures and methods which employ the concepts disclosed in this specification and the appended claims should fall within the scope of the present invention.

What is claimed is:

1. A cantilever probe card, which is provided between a device under test (DUT) and a tester, comprising:
a carrier board having a first side and a second side, wherein the first side faces the tester, and the second side faces the DUT;
a probe base provided on the second side of the carrier board, wherein the probe base is insulating;
two probes each having a tip and a cantilever, wherein the probes are conductive; the cantilever is connected to the tip; and the tip contacts a test pad of the DUT; and
a transmission device provided on the carrier board and electrically connected to the cantilevers of the probes respectively, wherein the transmission device is flexible, and has signal circuits; each of the signal circuits transmits test signals between one of the probes and the tester.

2. The cantilever probe card of claim 1, wherein the transmission device has a flexible printed circuit board, on which the signal circuits are provided.

3. The cantilever probe card of claim 1, wherein the transmission device has a plurality of coaxial cables, and cores of the coaxial cables are the signal circuits.

4. The cantilever probe card of claim 1, wherein the carrier board is provided with a through hole, through which the transmission device is provided, so that the transmission device has an end extending out from the first side of the carrier board to have the signal circuits connected to the tester, and an end extending out from the second side of the carrier board to have the signal circuits connected to the cantilevers of the probes respectively.

5. The cantilever probe card of claim 1, wherein the cantilever of each of the probes has a first section and a second section; the first section is connected to the tip, and is left out of the probe base; the second section is embedded in the probe base; and the transmission device is connected to the first sections of the cantilevers of the probes respectively.

6. The cantilever probe card of claim 1, wherein the cantilever of each of the probes has a first section and a second section; the first section is connected to the tip, and is left out of the probe base; the second section is embedded in the probe base; and the transmission device is connected to the second sections of the cantilevers of the probes respectively.

7. The cantilever probe card of claim 1, wherein the probe base has a first side and a second side opposite to the first side; the cantilever of each of the probes has a first section, a second section, and third section; the second section is embedded in the probe base while the first section and the third section extend out from the first side and the second side of the probe base respectively; the first section is connected to the tip; and the transmission device is connected to the third sections of the cantilevers of the probes respectively.

8. A cantilever probe card, which is provided between a device under test (DUT) and a tester, comprising:
a carrier board;
a probe base provided on the carrier board, wherein the probe base is insulating;
two probes each having a tip and a cantilever, wherein the probes are conductive; the cantilever is connected to the tip, and the tip contacts a test pad of the DUT;
a transmission device having signal circuits, wherein each of the signal circuits transmits test signals between one of the probes and the tester; and
a loopback device electrically connected to the signal circuits;
wherein when the DUT transmits a high-frequency test signal to one of the probes, the high-frequency test signal is transmitted through the signal circuit of the transmission device and the loopback device in sequence, and then is transmitted back to the DUT through the other probe.

9. The cantilever probe card of claim 8, wherein the transmission device has a flexible printed circuit board, on which the signal circuits are provided.

10. The cantilever probe card of claim 8, wherein the transmission device has a plurality of coaxial cables, and cores of the coaxial cables are the signal circuits.

11. The cantilever probe card of claim 8, wherein the cantilever of each of the probes has a first section and a second section; the first section is connected to the tip, and is left out of the probe base; the second section is embedded in the probe base; and the transmission device is connected to the first sections of the cantilevers of the probes respectively.

12. The cantilever probe card of claim 8, wherein the cantilever of each of the probes has a first section and a second section; the first section is connected to the tip, and is left out of the probe base; the second section is embedded in the probe base; and the transmission device is connected to the second sections of the cantilevers of the probes respectively.

13. The cantilever probe card of claim 8, wherein the probe base has a first side and a second side opposite to the first side; the cantilever of each of the probes has a first section, a second section, and third section; the second section is embedded in the probe base while the first section and the third section extend out from the first side and the second side of the probe base respectively; the first section is connected to the tip; and the transmission device is connected to the third sections of the cantilevers of the probes respectively.

14. The cantilever probe card of claim 8, wherein both the transmission device and the loopback device are embedded in the probe base.

15. The cantilever probe card of claim 8, wherein the transmission device is connected to the carrier board.

16. The cantilever probe card of claim 8, further comprising two inductive devices, each of which is electrically connected to the cantilever of one of the probes and the tester respectively, wherein while the tester generates a low-frequency test signal or a DC test signal, the test signal is transmitted to the DUT through one of the inductive device and the corresponding probe in sequence, and then the test signal is transmitted back to the tester through the other probe and the other inductive device in sequence.

17. The cantilever probe card of claim 16, wherein the inductive devices are chokes.
